(19) United States
(12) Patent Application Publication
(10) Pub. No.: US 2020/0389980 A1
(43) Pub. Date: Dec. 10, 2020

(54) Systems and Methods of Manufacturing Circuit Boards

(71) Applicant: OSI Electronics, Inc., Hawthorne, CA (US)

(72) Inventors: Konstantine Karavakis, Pleasanton, CA (US); Robert Jung, Fremont, CA (US)

(21) Appl. No.: 16/844,550

(22) Filed: Apr. 9, 2020

Related U.S. Application Data
(60) Provisional application No. 62/858,863, filed on Jun. 7, 2019.

(51) Int. Cl. H05K 3/12; H05K 3/00; H05K 3/46

(52) U.S. Cl. CPC H05K 3/125; H05K 3/0064; H05K 2203/0165; H05K 2203/013; H05K 3/4635

(57) ABSTRACT

A flexible circuit board including a substrate with a first side and an opposing second side, wherein the substrate is of a colorless polyimide; first and second circuit patterns formed by deposition of ink on the first and second sides, respectively; at least one opening to interconnect the first and second circuit patterns; and first and second cover layers applied on the first and second circuit patterns, respectively, wherein the first and second cover layers are of a colorless polyimide.

### CROSS-REFERENCE

The present specification relies on U.S. Patent Provisional Application No. 62/858,863, entitled “Systems and Methods of Manufacturing Circuit Boards”, filed on Jun. 7, 2019, for priority, which is herein incorporated by reference in its entirety.

### FIELD

The present specification is related generally to the field of circuit boards. More specifically, the present specification is related to manufacturing flexible circuit boards for use in medical devices, such as by integration into, or positioning on, contact lenses.

### BACKGROUND

Circuit boards, including flexible circuit boards (FCBs), are electronic circuits that are frequently used in a variety of modern electronic devices. A FCB comprises circuit traces and electronic components deposited onto a flexible substrate or laminate. FCBs typically comprise silicon substrates and etched thin metal foils and are so named because of their ability to bend, twist or flex. They have the advantage of being thin, thus saving space, and of being easily moldable to the shape of the electronic device. They are often used to form a connection between two separate circuits.

With continued demand for miniaturization and high-density circuit designs, circuit boards and FCBs have become more complex in design and manufacturing process. Certain medical applications such as, for example, contact lenses require circuitry to be placed on their periphery where width of the traces of the circuitry needs to be less than 1.25 mils. Positioning circuitry on contact lenses may be used to monitor physiological conditions of the human eye along with other sensing activities such as, but not limited to, monitoring glucose or blood sugar levels. The circuitry and the cover layer encapsulating the circuitry need to be flat so as to cause no discomfort to a person's eyes upon wearing the contact lenses.

In such contact lenses, standard fabrication methods employing plated holes or vias are fraught with limitations in that the cover layer protecting the traces of the circuitry may create a dimple over the via openings with a potential of cracking around the holes or vias. This may result in eye fluid to percolate into the holes or vias.

Thus, there is a need for improved processes of fabricating circuitry for applications such as, but not limited to, contact lenses that overcome the shortcomings of conventional fabrication methods.

### SUMMARY

The following embodiments and aspects thereof are described and illustrated in conjunction with systems, tools and methods, which are meant to be exemplary and illustrative, and not limiting in scope. The present application discloses numerous embodiments.

In some embodiments, the present specification discloses a flexible circuit board comprising: a substrate having a first side and an opposing second side, wherein the substrate comprises a colorless polyimide; a first circuit pattern formed by a deposition of ink on the first side; a second circuit pattern formed by a deposition of ink on the second side; at least one opening to interconnect the first circuit pattern to the second circuit pattern; a first cover layer applied on the first circuit pattern, wherein the first cover layer comprises a colorless polyimide; and a second cover layer applied on the second circuit pattern, wherein the second cover layer comprises a colorless polyimide.

Optionally, a thickness of the substrate ranges from 12 μm to 75 μm.

Optionally, a thickness of the first cover layer and the second cover layer each range from 12 μm to 25 μm.

Optionally, the at least one opening has a diameter ranging from 18 μm to 50 μm.

Optionally, the first circuit pattern is formed by conveying the first side passed a first print head of a printer and wherein the second circuit pattern is formed by conveying the second side passed the first print head of the printer.

Optionally, the ink comprises an infusion of nanoparticles of a conductive material comprising at least one of copper, silver or gold.

Optionally, the first cover layer is formed by conveying the first side passed a second print head of a printer and wherein the second cover layer is formed by conveying the second side passed the second print head of the printer.

Optionally, the at least one opening comprises ink and wherein the ink is deposited into the at least one opening during the deposition of the ink on at least one of the first side and the second side.

In some embodiments, the present specification discloses a method of manufacturing a flexible circuit board, the method comprising: obtaining a substrate having a first side and an opposing second side, wherein the substrate comprises a colorless polyimide; forming at least one opening, wherein said at least one opening extends through the substrate and interconnects the first side to the second side; depositing a first circuit pattern of ink on the first side of the substrate using a first print head of a printer; depositing a second circuit pattern of ink on the second side of the substrate using the first print head of the printer; depositing a first cover layer on the first side of the substrate using a second print head of the printer; and depositing a second cover layer on the second side of the substrate using the second print head of the printer, wherein the first and second cover layers do not cover at least portion of a surface of the first circuit pattern or the second circuit pattern.

Optionally, a thickness of the substrate ranges from 12 μm to 75 μm.

Optionally, a thickness of the first cover layer or the second cover layer ranges from 12 μm to 25 μm.

Optionally, the at least one opening has a diameter ranging from 18 μm to 50 μm.

Optionally, the first side of the substrate is conveyed passed the first print head of the printer configured to deposit the first circuit pattern and wherein the second side of the substrate is conveyed passed the first print head of the printer configured to deposit the second circuit pattern.

Optionally, the ink comprises an infusion of nanoparticles of a conductive material comprising at least one of copper, silver or gold.

Optionally, the first side of the substrate is conveyed facing the second print head of the printer configured to deposit the first cover layer and wherein the second side of the substrate is conveyed facing the second print head of the printer configured to deposit the second cover layer.

Optionally, the method further comprises filling the at least one opening with ink concurrent to depositing the ink on at least one of the first side or second side.

In some embodiments, the present specification discloses a method of manufacturing a flexible circuit board, the method comprising: obtaining a substrate having first and second opposing sides, wherein the substrate comprises a colorless polyimide; forming at least one opening, wherein the at least one opening extends through the substrate and interconnects the first side with the opposing second side; panel plating the first side and the second side of the substrate using a conducting metal; applying a photoresist on the first side and the second side; exposing the photoresist to light; etching the conducting metal to form a first circuit pattern on the first side and a second circuit pattern on the second side; and encapsulating the first side with a first cover layer and the second side with a second cover layer, and wherein the first and second cover layers are positioned to not cover at least a portion of a surface of the first circuit pattern or a surface of the second circuit pattern, thereby leaving said surface of the first circuit pattern or said surface of the second circuit pattern exposed; and subjecting said exposed surface of the first circuit pattern or said exposed surface of the second circuit pattern to a surface finish process.

Optionally, each of the first cover layer and the second cover layer is applied using at least one of inkjet printing, screen printing or vacuum lamination of dry film.

Optionally, the method further comprises filling the at least one opening with the conducting metal concurrent with the panel plating of at least one of the first side or the second side.

Optionally, a thickness of the substrate ranges from 12 μm to 75 μm.

The aforementioned and other embodiments of the present shall be described in greater depth in the drawings and detailed description provided below.

### BRIEF DESCRIPTION OF THE DRAWINGS

These and other features and advantages of the present specification will be further appreciated, as they become better understood by reference to the following detailed description when considered in connection with the accompanying drawings:

FIG. 1 illustrates a cross-sectional view of a flexible circuit board (FCB), in accordance with some embodiments of the present specification;

FIG. 2 illustrates a cross-sectional view of a flexible substrate, in accordance with some embodiments of a first method of manufacturing of the present specification;

FIG. 3 illustrates a cross-sectional view of the flexible substrate with at least one formed via, in accordance with some embodiments of the first method of manufacturing of the present specification;

FIG. 4A illustrates a cross-sectional view of the flexible substrate being subjected to inkjet printing to form a circuitized or patterned FCB, in accordance with some embodiments of the first method of manufacturing of the present specification;

FIG. 4B illustrates a cross-sectional view of the circuitized or patterned FCB encapsulated on both sides, respectively, by first and second cover layers, in accordance with some embodiments of the first method of manufacturing of the present specification;

FIG. 5 is a flowchart of a plurality of exemplary steps of a first method of manufacturing an FCB, in accordance with some embodiments of the present specification;

FIG. 6 illustrates a cross-sectional view of a flexible substrate, in accordance with some embodiments of a second method of manufacturing of the present specification;

FIG. 7 illustrates a cross-sectional view of the flexible substrate with at least one formed via, in accordance with some embodiments of the second method of manufacturing of the present specification;

FIG. 8 illustrates a cross-sectional view of the flexible substrate with first and second conducting layers, in accordance with some embodiments of the second method of manufacturing of the present specification;

FIG. 9A illustrates a cross-sectional view of the flexible substrate with photoresist applied to the first and second conducting layers, in accordance with some embodiments of the second method of manufacturing of the present specification;

FIG. 9B illustrates a cross-sectional view of the flexible substrate with first and second circuit patterns, in accordance with some embodiments of the second method of manufacturing of the present specification;

FIG. 10 illustrates a cross-sectional view of the circuitized or patterned FCB encapsulated on both sides, respectively, by first and second cover layers, in accordance with some embodiments of the second method of manufacturing of the present specification;

FIG. 11 is a flowchart of a plurality of exemplary steps of a second method of manufacturing an FCB, in accordance with some embodiments of the present specification;

FIG. 12 illustrates a cross-sectional view of a flexible conductor-clad base film, in accordance with some embodiments of a third method of manufacturing of the present specification;

FIG. 13 illustrates a cross-sectional view of the flexible conductor-clad base film with at least one formed via, in accordance with some embodiments of the third method of manufacturing of the present specification;

FIG. 14 illustrates a cross-sectional view of the flexible conductor-clad base film with the at least one via being subjected to shadow plating, in accordance with some embodiments of the third method of manufacturing of the present specification;

FIG. 15 illustrates a cross-sectional view of the flexible conductor-clad base film with the at least one via filled with conducting material, in accordance with some embodiments of the third method of manufacturing of the present specification;

FIG. 16 illustrates a cross-sectional view of the flexible conductor-clad base film with first and second circuit patterns, in accordance with some embodiments of the third method of manufacturing of the present specification;

FIG. 17 illustrates a cross-sectional view of the circuitized or patterned FCB encapsulated on both sides, respectively, by first and second cover layers, in accordance with some embodiments of the third method of manufacturing of the present specification; and,

FIG. 18 is a flowchart of a plurality of exemplary steps of a third method of manufacturing an FCB, in accordance with some embodiments of the present specification.

### DETAILED DESCRIPTION

The present specification discloses a flexible circuit board (FCB), semi-rigid circuit board, or rigid circuit board fabricated using clear or colorless polyimide films as substrate material as well as for cover layers of the FCB, semi-rigid, or rigid circuit board. The present specification discloses systems and methods of manufacturing circuit boards for medical application such as, for example, contact lenses so that surface of a contact lens is smooth and flat after application of cover layer(s).

A “via” (vertical interconnect access) is an electrical connection between layers in a flexible electronic circuit that passes through the plane of one or more layers.

A “flexible circuit board” is a circuit board that may be contorted, twisted, or bent about a plane, using a first level of force, in order to conform to a desired shape without damaging or breaking the circuit board or the traces thereon.

A “semi-rigid circuit board” is a circuit board that may be contorted, twisted, or bent about a plane, using a second level of force, in order to conform to a desired shape without damaging or breaking the circuit board or the traces thereon, where the second level of force is greater than the first level of force to achieve the same shape.

A “rigid circuit board” is a circuit board with a fixed shape that cannot be contorted, twisted, or bent about a plane without damaging or breaking the circuit board or the traces thereon.

A “computing device” is at least one of a cellular phone, PDA, smart phone, tablet computing device, custom kiosk, or other computing device capable of executing programmatic instructions. The “computing device” may be coupled to at least one display. The “computing device” further comprises at least one processor to control the operation of an inkjet printer and its components.

The present specification is directed towards multiple embodiments. The following disclosure is provided in order to enable a person having ordinary skill in the art to practice the invention. Language used in this specification should not be interpreted as a general disavowal of any one specific embodiment or used to limit the claims beyond the meaning of the terms used therein. The general principles defined herein may be applied to other embodiments and applications without departing from the spirit and scope of the invention. Also, the terminology and phraseology used is for the purpose of describing exemplary embodiments and should not be considered limiting. Thus, the present invention is to be accorded the widest scope encompassing numerous alternatives, modifications and equivalents consistent with the principles and features disclosed. For purpose of clarity, details relating to technical material that is known in the technical fields related to the invention have not been described in detail so as not to unnecessarily obscure the present invention.

In the description and claims of the application, each of the words “comprise” “include” and “have”, and forms thereof, are not necessarily limited to members in a list with which the words may be associated. It should be noted herein that any feature or component described in association with a specific embodiment may be used and implemented with any other embodiment unless clearly indicated otherwise.

As used herein, the indefinite articles “a” and “an” mean “at least one” or “one or more” unless the context clearly dictates otherwise.

### Circuit Board Overview

The circuit boards disclosed in the embodiments of the present specification comprise flexible, semi-rigid, or rigid circuit boards and the methods of manufacture disclosed in the embodiments of the present specification can be used to manufacture flexible, semi-rigid, or rigid circuit boards. In some embodiments, flexibility of the circuit board is dependent on the number of layers comprising the circuit board. In some embodiments, for example, for a multilayer circuit board having more than two layers, the final board thickness will increase the rigidity of the board making the board semi-rigid or rigid. While the following figures are described with reference to a double-layered or double-sided flexible circuit board (FCB), they also apply to multi-layered FCBs. Also, while the following figures are described with reference to a flexible FCB, they also apply to semi-rigid and rigid circuit boards.

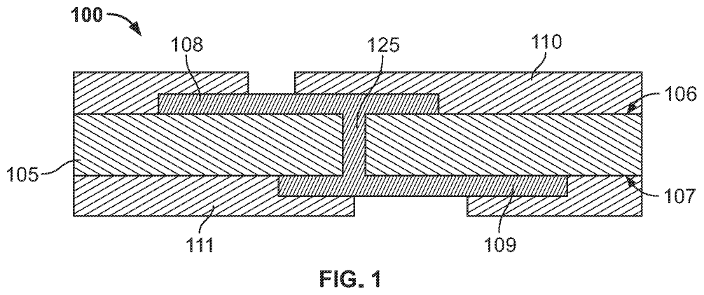

FIG. 1 illustrates a cross-sectional view of a flexible circuit board 100, in accordance with some embodiments of the present specification. In some embodiments, the FCB 100 comprises a flexible layer or film comprising a dielectric insulating substrate or base film 105 having a first side 106 and an opposing second side 107. In various embodiments, the first and second sides 106, 107 respectively comprise first and second circuit patterns 108, 109. In embodiments, each of the first and second circuit patterns 108, 109 comprise a plurality of surface-mounted electronic components that are electrically connected to each other through a plurality of conductive pads or lands, conductive traces, and conductive vias such as via 125. A conductive via is a hole lined and/or filled with conductive material.

In some embodiments, the conductive via 125 interconnects the first and second circuit patterns 108, 109 that are formed on the first and second sides 106, 107 of the substrate 105.

Vias may be through-hole, blind and/or buried vias depending upon the design, interconnection needs and the number of layers (in case of multi-layered circuit boards) of a FCB. In some embodiments, interconnection between the first and second circuit patterns 108, 109 is accomplished with at least one via, such as via 125, that is preferably formed as a small through-hole (instead of a blind via) for flexing reliability and cleanliness of the through-hole or via. Persons of ordinary skill in the art would appreciate that there is no base copper at the bottom of a through-hole or via compared to a blind via where copper is present at the bottom causing contamination.

The FCB 100 further comprises first and second cover layers 110, 111 that are applied and tacked in place over the first and second sides 106, 107, respectively, in order to protect the plurality of conductive pads and traces of the first and second circuit patterns 108, 109.

In preferred embodiments, the substrate 105 of the FCB 100 comprises a clear or colorless polyimide. In various embodiments, the substrate layer 105 comprises a flexible electrically insulating (dielectric) material such as, but not limited to, polyimide (PI), polyether ether ketone (PEEK), polyester (PET), polyethylene naphthalate (PEN), polyetherimide (PEI), along with various fluoropolymers (FEP) and polyimide copolymer films, or other flexible insulating materials including polyester or silk. In still other embodiments, the substrate layer 105 is comprised of liquid crystal polymer (LCP) material. LCPs are compounds made of partially crystalline aromatic polyesters. Non-limiting examples of LCPs which may be used as polymer films in the fabrication of the substrate 105 and cover layers 110, 111 include polyesters comprising monomer units derived from 4-hydroxybenzoic acid and 2,6-hydroxynaphthoic acid, a polyester comprising monomer units derived from 2,6-hydroxynaphthoic acid, terephthalic acid and acetaminophen, and a polyester comprising monomer units derived from 4-hydroxybenzoic acid, terephthalic acid and 4,4′-biphenol. More broadly, LCPs which may be used as polymer films in the fabrication of the substrate 105 include polyesters comprising at least one of the following: one or more aromatic dicarboxylic acids and alicyclic dicarboxylic acids; one or more aromatic diols, alicyclic diols and aliphatic diols; one or more aromatic hydroxy-carboxylic acids; one or more aromatic thiocarboxylic acids; one or more aromatic dithiols and aromatic dithiophenols; and/or one or more aromatic hydroxy hydroxylamines and aromatic diamines. In some embodiments, a thickness of the substrate layer 105 ranges from 12 μm to 50 μm. In some embodiments, a thickness of the substrate layer 105 ranges from 12 μm to 75 μm.

In some embodiments, the cover layers 110, 111 comprise any of the materials mentioned above with reference to the substrate layer 105. In some embodiments, the cover layers 110, 111 comprise any of the materials mentioned above with reference to the substrate layer 105 and that can preferably be made colorless. In various embodiments, thickness of each of the cover layers 110, 111 ranges from 12 82 m to 25 μm.

### A First Embodiment of the Manufacturing Process

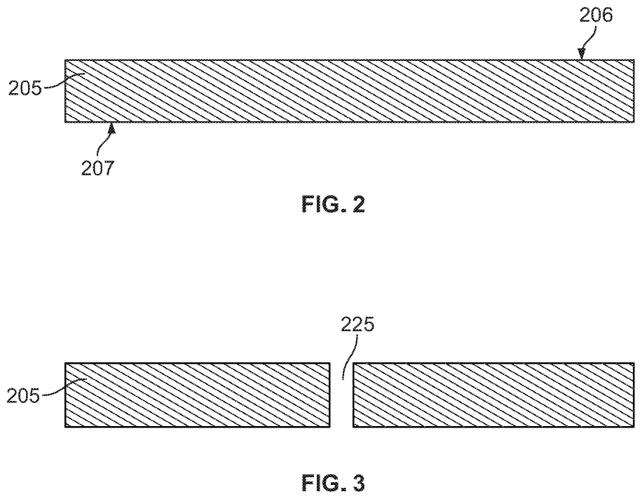

FIG. 2 illustrates a cross-sectional view of a flexible substrate 205, in accordance with embodiments of the present specification. Referring to FIG. 2, the starting material of the FCB (such as the FCB 100 of FIG. 1) is the flexible substrate 205 having a first side 206 and a second opposing side 207. In some embodiments, the flexible substrate 205 is a substantially rectangular strip of a predetermined length to support fabrication, thereon, of at least one FCB. In some embodiments, the flexible substrate 205 is received in the form of a roll or sheet and cut to size in order to fabricate at least one FCB thereon. In some embodiments, a thickness of the substrate layer 205 may range from 12 micron to 50 micron. In some embodiments, a thickness of the substrate layer 205 may range from 12 micron to 75 micron.

FIG. 3 illustrates a cross-sectional view of the substrate 205 with at least one formed opening, hole or via, in accordance with some embodiments. Referring now to FIG. 3, at least one opening, hole or via 225 is formed in the substrate 205 by an ultraviolet (UV) based laser, a carbon dioxide based laser, or by any other known methods, such as, but not limited to, mechanical drilling, depth-controlled laser drilling or punching and H₂O jet. In an embodiment, for exemplary illustrative purposes, the via 225 is shown as a single through-hole. However, in alternate embodiments a plurality of through-hole, blind and/or buried vias may be formed depending upon the desired design and surface mount of the FCB. In some embodiments, laser systems use panel edges for reference points to laser drill the required one or more vias including target holes or vias that may be needed in subsequent steps such as, for example, during formation of cover layers. In various embodiments, one or more openings or holes, formed in the FCB, comprise at least one of the following types: a) tooling holes formed outside of formed circuit areas for positioning the substrate 205 during subsequent processing. The sequence of FCB fabrication steps requires close alignment from one process to the next, and the tooling holes are used with locating pins at each step to achieve accurate registration/alignment; b) insertion holes for inserting electronic component leads therein; and c) via holes, such as the at least one via 225, that are later filled with conductive ink and used as conducting paths between the first and second sides of the FCB.

In some embodiments, the at least one via 225 has a diameter ranging from 18 micron to 50 micron. In some embodiments, the at least one via 225 has a diameter ranging from 25 micron to 50 micron. In some embodiments, an aspect ratio (defined as a ratio of a length or depth of the via to its diameter) for the at least one via 225 ranges from 0.8 to 1.0. In embodiments, a diameter and/or aspect ratio of the at least one via 225 depends at least on a thickness of the dielectric substrate 205. It should be appreciated that smaller diameter of the at least one via 225 leads to improved wiring density and easier filling of the at least one via 225 with conductive paste or ink thereby eliminating the possibilities of issues such as, for example, voids, and dimples. In some embodiments, once the at least one opening, hole or via 225 is formed in the substrate 205 the via is cleaned or de-smeared using plasma cleaning to remove unwanted residue or by-products left behind by laser or mechanical drilling of the at least one via 225.

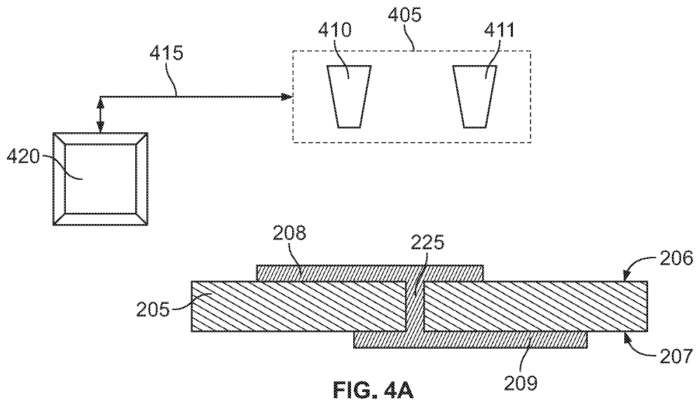

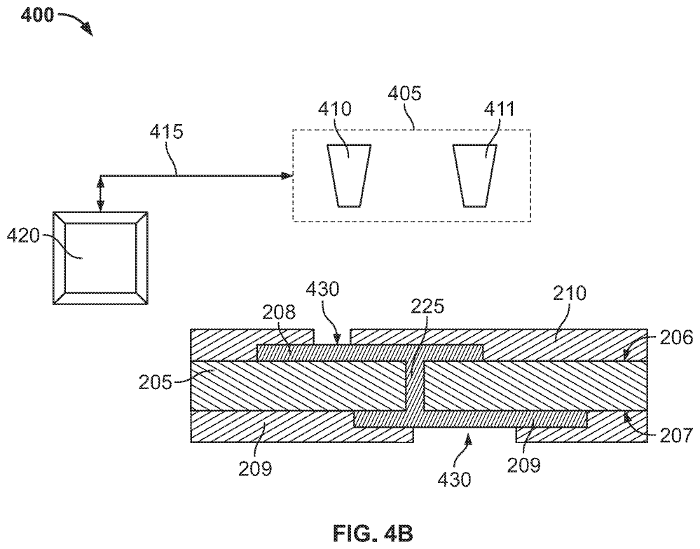

Referring now to FIG. 4A, a conveyor moves the substrate 205 with the at least one via 225 through a printing region of an inkjet printer 405 such that the first side 206 is facing a first print head 410 of the inkjet printer 405. In embodiments, the inkjet printer 405 is in data communication with a computing device 420 via a communication link 415 that may be wired or wireless. In some embodiments, the first print head 410 is in fluid communication with a first reservoir while a second print head 411 is in fluid communication with second reservoir. The first reservoir stores conductive ink while the second reservoir stores cover layer material. In embodiments, the cover layer material is same as the material for the substrate 205 thereby providing similar physical properties (such as, but not limited to, the coefficient of thermal expansion (CTE)) for better reliability. In embodiments, the computing device 420 pre-stores first and second pattern layouts corresponding to the desired first and second circuit patterns 208, 209 to be printed on the first and second sides 206, 207.

In embodiments, conductive ink contains an infusion of nanoparticles of conductive material such as, but not limited to, copper, silver or gold. As known to persons of ordinary skill in the art, silver has better resistivity than copper and as a result silver is a better conductor. The resistivity of silver is 1.59×10⁻⁸ Ohm-m while that of copper is 1.68×10⁻⁸ Ohm-m. Silver nanoparticles infused ink, such as those manufactured by ChemCubed, have resistivity values close to pure silver and ranging between 1.9 to 2.0×10⁻⁸ Ohm-m.

During operation, the computing device 430 communicates the first pattern layout to the inkjet printer 405. As the first side 206 of the substrate 205 is conveyed under the first print head 410, a printing process is carried out wherein the first print head 410 receives conductive ink from the first reservoir and deposits a pattern of the conductive ink onto the first side 206, in accordance with the first pattern layout, thereby forming the first circuit pattern 208 on the substrate 205. In accordance with aspects of the present specification, the at least one via 225 gets filled with the conductive ink as the printing process is carried out on the first side of the substrate 205. In some embodiments, a release film, preferably with a plurality of holes to assist in proper holding of the FCB panel using vacuum, is placed on the printer stage. The release film comprises commonly used films such as, for example, Teflon and Tedlar®. In some embodiments, a thickness of the release film ranges from 25 to 150 μm. The plurality of holes on the release film are not positioned directly on top of the at least one via but away and preferably in areas of the periphery of the FCB panel. It should be appreciated that ink jet printers typically use alignment target holes as reference points for accurate placement of the ink. In some embodiments, these target holes are made by a laser drilling process. The deposited ink, for the first circuit pattern 208, is then tack dried in an oven. In embodiments, the conductive ink is thermally curable or UV (Ultra Violet) curable. In the case of UV curable inks the printer 405 includes one or more UV lamps that cure the ink as it gets printed at 500-1500 Mj.

To generate or form the second circuit pattern 209, the substrate 205 is flipped over so that the second side 207 is facing the first print head 410 of the inkjet printer 405. The computing device 430 now communicates the second pattern layout to the inkjet printer 405. As the second side 207 of the substrate 205 is conveyed under the first print head 410, the printing process is carried out wherein the first print head 410 receives conductive ink from the first reservoir and deposits a pattern of the conductive ink onto the second side 207, in accordance with the second pattern layout, thereby forming the second circuit pattern 209 on the substrate 205. The deposited ink, for the second circuit pattern 209, is then tack dried in an oven.

It should be appreciated that in situations where the at least one via 225 is a through hole, deposition of ink to form the first and second circuit patterns 208, 209 also simultaneously results in filling the at least one via 225 with the conductive ink, from both sides 206, 207, as the printing process is carried out on both—the first and second sides 206, 207 of the substrate 205.

As shown in FIG. 4B, in accordance with aspects of the present specification, the first and second sides 206, 207 are respectively encapsulated by first and second cover layers or films 210, 211 to protect the formed first and second circuit patterns 208, 209, comprising conductive trace patterns and pads, against oxidation and mechanical stress or wear. In some embodiments, the first and second cover layers 210, 211 comprise clear or colorless material such as, but not limited to, clear/colorless polyimide. In various alternate embodiments, the first and second cover layers 210, 211 comprise any dielectric material, for use in circuit board applications, that can be made colorless.

In some embodiments, the first and second cover layers 210, 211 are deposited using the inkjet printing process. Referring back to FIG. 4B, during operation, the computing device 430 communicates a first cover layer layout to the inkjet printer 405. As the first side 206 of the FCB 400 is conveyed under the second print head 411, a printing process is carried out wherein the second print head 411 receives cover layer material from the second reservoir and deposits a pattern corresponding to the first cover layer 210 onto the first side 206 of the substrate 205, as defined by a first cover layer layout communicated by the computing device 430 to the inkjet printer 405.

To deposit the second cover layer 211, the FCB 400 is flipped over so that the second side 207 is facing the second print head 411 of the inkjet printer 405. The computing device 430 now communicates a second cover layer layout to the inkjet printer 405. As the second side 207 of the FCB 400 is conveyed under the second print head 411, the printing process is carried out wherein the second print head 411 receives cover layer material from the second reservoir and deposits a pattern corresponding to the second cover layer 211 onto the second side 207, as defined by a second cover layer layout communicated by the computing device 430 to the inkjet printer 405.

It should be appreciated that, in alternate embodiments, the first and second cover layers 210, 211 may be formed using methods such as, for example, screen printing and vacuum lamination of dry film. In embodiments where dry film cover layers are used, one or more openings in the dry film are created using laser and the dry film is aligned to the pads on the FCB 400 and tacked in place prior to vacuum lamination.

It should be appreciated that, in some embodiments, the material for the first and second cover layers 210, 211 is the same as that of the substrate 205 and can be formulated for ink jet applications by adjusting the rheological properties of the material. In some embodiments, solder mask cover layers which are typically applied by screen printing methods can be also applied by inkjet printing.

As shown in FIG. 4B, the FCB 400 encapsulated with the first and second cover layers 210, 211 may have certain conducting ink surfaces, surface portions or surface areas 430 exposed to enable an end-user to attach necessary components at the exposed surfaces. For example, the end-user may attach surface mountable components such as, for example, resistors, capacitors, BGA package, or any pin connector through a plated through hole. In some embodiments, the exposed surfaces 430 are subjected to a surface finish process to prevent the underlying conductive traces (of copper, for example) from oxidizing or corroding. The surface finish processes comprise treatments such as, but not limited to, ENIG (Electroless Nickel Immersion Gold), silver, tin, ENEPIG (Electroless Nickel Electroless Palladium Immersion Gold) and solder.

Thereafter, electrical testing of the FCB 400 is conducted. In some embodiments, the electrical testing is a continuity check for shorts, opens and voltage leakage. In embodiments, where fabrication of a plurality of FCBs is done on a single panel, each of the plurality of FCBs is laser routed (or alternatively, mechanically routed) for singulation. The FCBs are subjected to final inspection and testing.

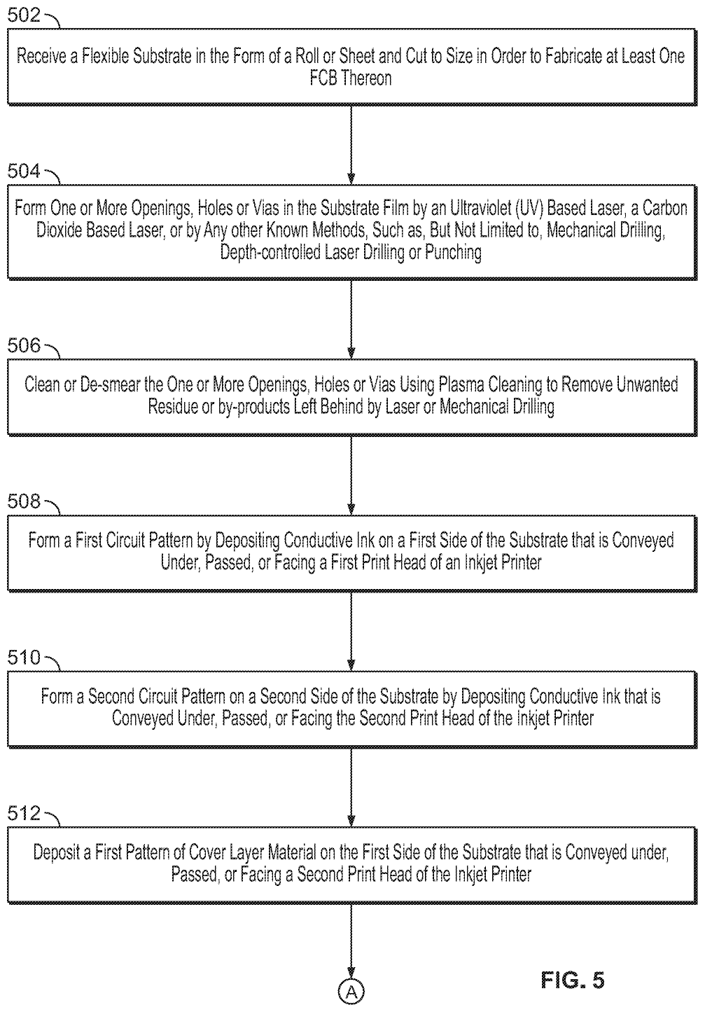

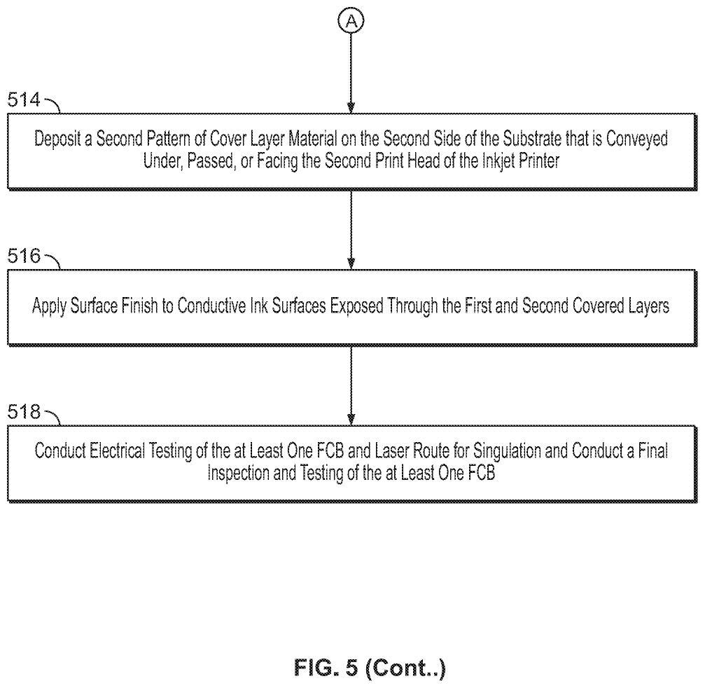

FIG. 5 is a flowchart of a plurality of exemplary steps of a first method of manufacturing an FCB, in accordance with some embodiments of the present specification. At step 502, a flexible substrate film is received in the form of a roll or sheet and cut to size in order to fabricate at least one FCB thereon. In some embodiments, the flexible substrate has a first side and an opposing second side. In some embodiments, the substrate film is of a clear or colorless polyimide.

At step 504, one or more openings, holes or vias are formed in the substrate film by an ultraviolet (UV) based laser, a carbon dioxide based laser, or by any other known methods, such as, but not limited to, mechanical drilling, depth-controlled laser drilling or punching. In some embodiments, the one or more vias extend through the substrate layer and the first and second opposing sides. In various embodiments, one or more through-hole, blind and/or buried vias may be formed depending upon the desired design and surface mount of the FCB. At step 506, the one or more openings, holes or vias are cleaned or de-smeared using plasma cleaning to remove unwanted residue or by-products left behind by laser or mechanical drilling.

At step 508, the first side of the substrate film is conveyed under a first print head of an inkjet printer. The first print head receives conductive ink from a first reservoir and deposits a pattern of the conductive ink to form a first circuit pattern or traces on the first side of the substrate film. The pattern of conductive ink deposited is defined by a first pattern layout communicated to the inkjet printer by a computing device. The one or more vias are metallized or made conductive as they get filled with the conductive ink during the printing process carried out on the first side of the substrate. The deposited ink, for the first circuit pattern, is then tack dried in an oven. In some embodiments, the conductive ink is curable using one or more UV lamps that are included in the inkjet printer for use during the printing process.

At step 510, the substrate film is turned over so that the second side of the substrate film is conveyed under the first print head of the inkjet printer. The first print head deposits another pattern of the conductive ink to form a second circuit pattern or traces on the second side of the substrate film. The pattern of conductive ink deposited is defined by a second pattern layout communicated to the inkjet printer by the computing device. The deposited ink, for the second circuit pattern, is then tack dried in an oven. In embodiments where the one or more vias are through holes, deposition of ink to form the first and second circuit patterns also simultaneously results in filling the one or more vias with the conductive ink as the printing process is carried out on both—the first and second sides of the substrate.

At step 512, the first side of the substrate film is conveyed again under a second print head of the inkjet printer. The second print head receives cover layer material from a second reservoir and deposits a first pattern of the cover layer material defined by a first cover layer layout (to form a first cover layer) communicated to the inkjet printer by the computing device. At step 514, the substrate film is turned over so that the second side of the substrate film is conveyed again under the second print head of the inkjet printer. The second print head receives cover layer material from the second reservoir and deposits a second pattern of the cover layer material defined by a second cover layer layout (to form a second cover layer) communicated to the inkjet printer by the computing device.

It should be appreciated that, in alternate embodiments, the first and second cover layers may be formed using methods such as, for example, screen printing and vacuum lamination of dry film.

In some embodiments, the first and second cover layers may have certain conducting ink surfaces, surface portions or surface areas exposed to enable an end-user to attach necessary components at the exposed surfaces. For example, the end-user may attach surface mountable components such as, for example, resistors, capacitors, BGA package, or any pin connector through a plated through hole. At step 516, in some embodiments, the exposed surfaces are subjected to a surface finish process to prevent the underlying conductive traces (of copper, for example) from oxidizing or corroding. The surface finish processes comprise treatments such as, but not limited to, ENIG (Electroless Nickel Immersion Gold), silver, tin, ENEPIG (Electroless Nickel Electroless Palladium Immersion Gold) and solder.

Finally, at step 518, electrical testing of the FCB 400 is conducted. In some embodiments, the electrical testing is a continuity check for shorts, opens and voltage leakage. In embodiments, where fabrication of a plurality of FCBs is done on a single panel, each of the plurality of FCBs is laser routed (or alternatively, mechanically routed) for singulation. The FCBs are subjected to final inspection and testing.

### A Second Embodiment Of The Manufacturing Process

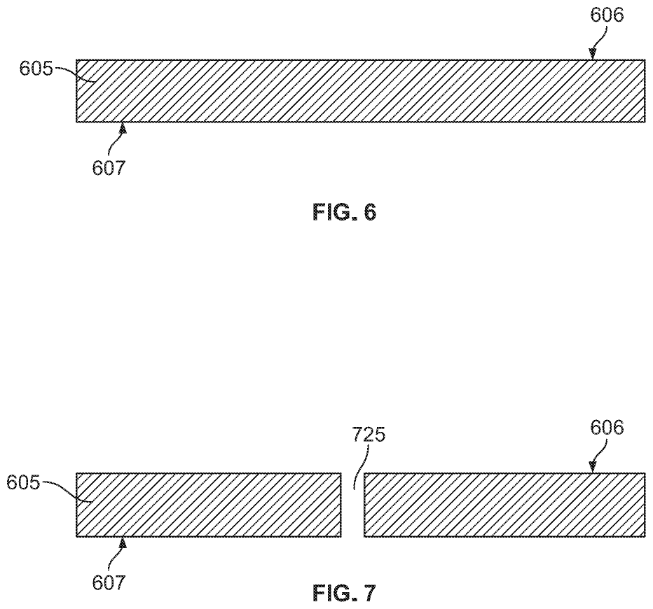

FIG. 6 illustrates a cross-sectional view of a flexible substrate 605, in accordance with embodiments of the present specification. Referring to FIG. 6, the starting material of the FCB is the flexible substrate 605 having a first side 606 and a second opposing side 607. In some embodiments, the flexible substrate 605 is a substantially rectangular strip of a predetermined length to support fabrication, thereon, of at least one FCB. In some embodiments, the flexible substrate 605 is received in the form of a roll or sheet and cut to size in order to fabricate at least one FCB thereon. In some embodiments, a thickness of the substrate layer 605 may range from 12 micron to 50 micron. In some embodiments, a thickness of the substrate layer 205 may range from 12 micron to 75 micron.

FIG. 7 illustrates a cross-sectional view of the substrate 605 with at least one formed opening, hole or via, in accordance with some embodiments. Referring now to FIG. 7, at least one opening, hole or via 725 is formed in the substrate 605 by an ultraviolet (UV) based laser, a carbon dioxide based laser, or by any other known methods, such as, but not limited to, mechanical drilling, depth-controlled laser drilling or punching and H₂O jet. In an embodiment, for exemplary illustrative purposes, the via 725 is shown as a single through-hole. However, in alternate embodiments a plurality of through-hole, blind and/or buried vias may be formed depending upon the desired design and surface mount of the FCB. In some embodiments, laser systems use panel edges for reference points to laser drill the required one or more vias including target holes or vias that may be needed in subsequent steps such as, for example, during formation of cover layers. In various embodiments, one or more openings or holes, formed in the FCB, comprise at least one of the following types: a) tooling holes formed outside of formed circuit areas for positioning the substrate 205 during subsequent processing. The sequence of FCB fabrication steps requires close alignment from one process to the next, and the tooling holes are used with locating pins at each step to achieve accurate registration/alignment; b) insertion holes for inserting electronic component leads therein; and c) via holes, such as the at least one via 725, that are later made conductive and used as conducting paths between the first and second sides of the FCB.

In some embodiments, the at least one via 725 has a diameter ranging from 18 micron to 50 micron. In some embodiments, the at least one via 725 has a diameter ranging from 25 micron to 50 micron. In some embodiments, once the at least one opening, hole or via 725 is formed in the substrate 705 the via is cleaned or de-smeared using plasma cleaning to remove unwanted residue or by-products left behind by laser or mechanical drilling of the at least one via 725.

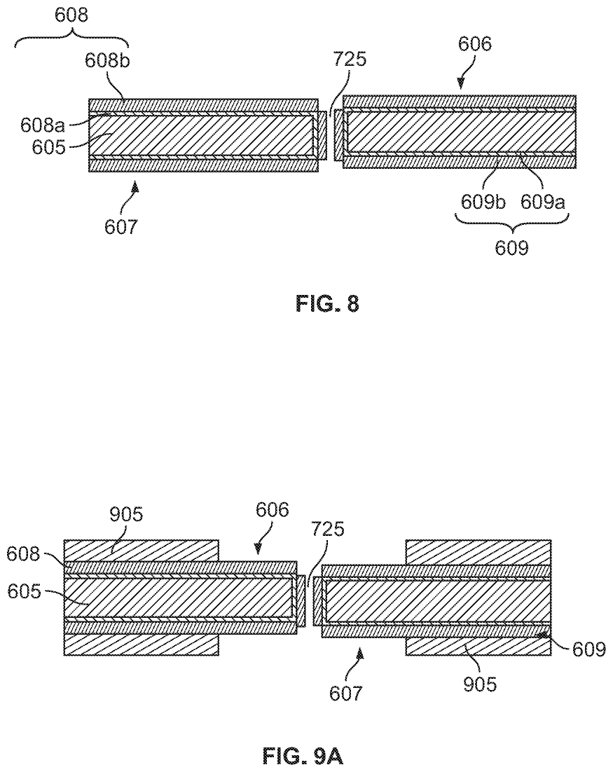

As shown in FIG. 8, first and second conducting layers 608, 609 are formed on the first and second sides 606, 607, respectively, of the substrate 605 as well as through the at least one via 725. In some embodiments, each of the first and second conducting layers 608, 609 comprises first and second metallic tie-coat layers 608a, 609a such as, for example, of nickel, chromium or a metallic alloy followed by first and second layer 608b, 609b of copper. In some embodiments, the tie-coat layers 608a, 609a have a thickness ranging from 5 Angstrom to 10 Angstrom. In some embodiments, the copper layers 608b, 609b have a thickness ranging from 1000 Angstrom to 2000 Angstrom.

In alternate embodiments, each of the first and second conducting layers 608, 609 (formed on the first and second sides 606, 607 and through the at least one via 725) comprises only copper.

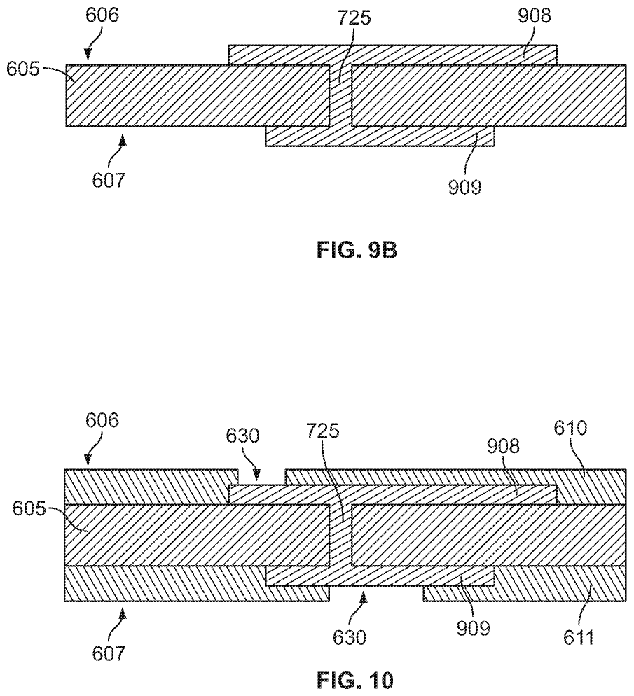

Referring now to FIGS. 9A, a light sensitive dry film photoresist 905 is applied on the first and second conducting layers 608, 609. The photoresist 905 is exposed to light and developed in the area of the at least one via 725 as well as in traces that would later be metallized to form first and second circuit patterns 908, 909 (FIG. 9B) on the first and second sides 606, 607, respectively. In embodiments, the at least one via 725 has a diameter ranging from 12 micron to 25 micron.

As shown in FIG. 9B, in some embodiments, the FCB of FIG. 9A is immersed in a series of copper plating baths that include a catalyst (usually palladium) followed by an alkaline, chelated solution of copper. Consequently, copper is electrolytically deposited onto the traces (developed in the processing step of FIG. 9A) thereby forming the first and second circuit patterns 908, 909 as well as filling the at least one via 725 with copper. In some embodiments, copper baths such as, for example, MacDermid® VF-150 or Uyemura® are used to fill the at least one via 725 while plating less on the surfaces. Subsequent fabrication steps comprise—plating tin on exposed copper surfaces to protect them from being etched, stripping the photoresist 905, etching the thin base copper that lies in between the copper plated features and then strip the tin.

In some alternate embodiments, the surfaces on the first and second sides 606, 607 of the substrate 605 of FIG. 7 are panel plated, using copper, and the at least one via 725 is also simultaneously filled with copper. Subsequent fabrication steps comprise—coating resist, exposing the resist to light, developing and etching the copper between traces (to form first and second circuit patterns 908, 909 as shown in FIG. 9B) and eventually stripping the resist.

As a next step, as shown in FIG. 10, in some embodiments, first and second cover layers 610, 611 are deposited or formed (on the first and second sides 606, 607) using methods such as, for example, the inkjet printing process described earlier with reference to FIG. 4B, screen printing or vacuum lamination of dry film. Consequently, the first and second sides 606, 607 are respectively encapsulated by the first and second cover layers or films 610, 611 to protect the formed first and second circuit patterns 608, 609, comprising conductive trace patterns and pads, against oxidation and mechanical stress or wear. In some embodiments, the first and second cover layers 610, 611 comprise clear or colorless material such as, but not limited to, clear/colorless polyimide or any other dielectric or solder mask that can be made colorless. As shown in FIG. 10, the FCB 1000 encapsulated with the first and second cover layers 610, 611 may have certain conducting surfaces, surface portions or surface areas 630 exposed to enable an end-user to attach necessary components at the exposed surfaces. For example, the end-user may attach surface mountable components such as, for example, resistors, capacitors, BGA package, or any pin connector through a plated through hole. In some embodiments, the exposed surfaces 630 are subjected to a surface finish process to prevent the underlying conductive traces (of copper, for example) from oxidizing or corroding. The surface finish processes comprise treatments such as, but not limited to, ENIG (Electroless Nickel Immersion Gold), silver, tin, ENEPIG (Electroless Nickel Electroless Palladium Immersion Gold) and solder.

Thereafter, electrical testing of the FCB 1000 is conducted. In some embodiments, the electrical testing is a continuity check for shorts, opens and voltage leakage. In embodiments, where fabrication of a plurality of FCBs is done on a single panel, each of the plurality of FCBs is laser routed (or alternatively, mechanically routed) for singulation. The FCBs are subjected to final inspection and testing.

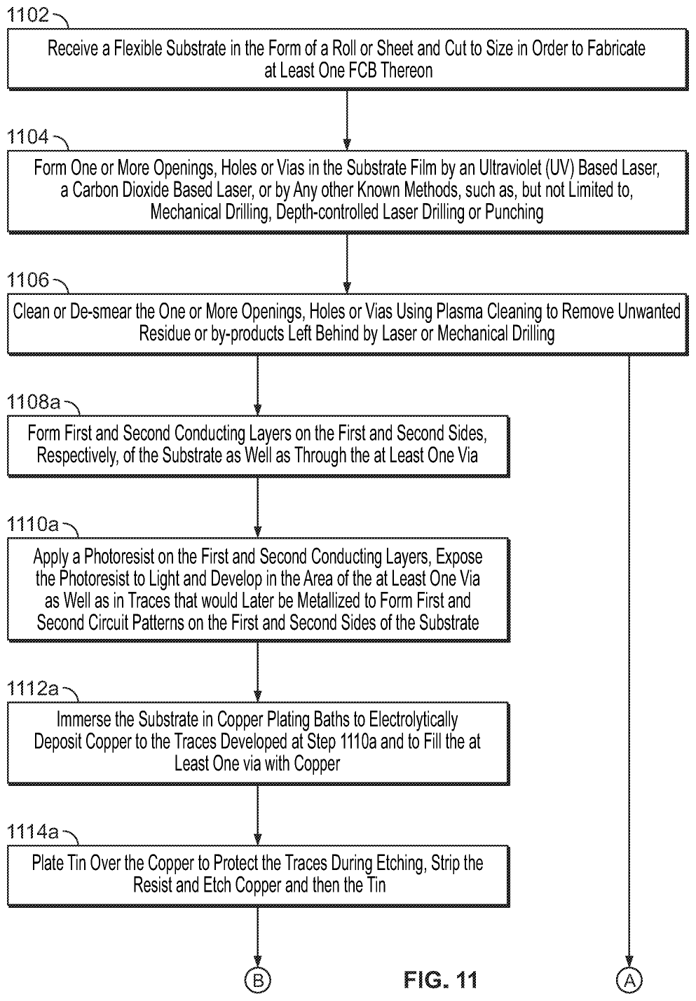

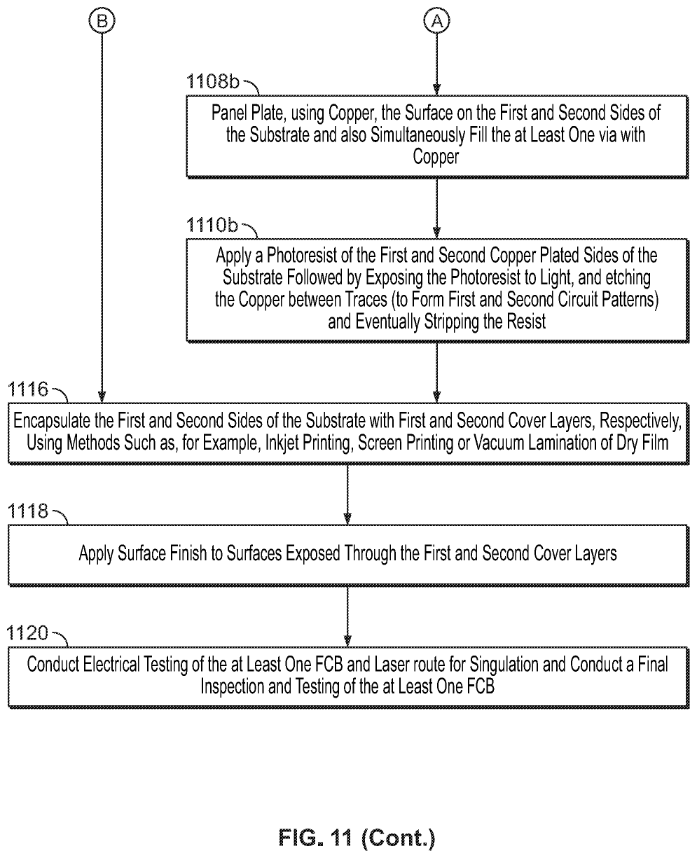

FIG. 11 is a flowchart of a plurality of exemplary steps of a second method of manufacturing an FCB, in accordance with some embodiments of the present specification. At step 1102, a flexible substrate film is received in the form of a roll or sheet and cut to size in order to fabricate at least one FCB thereon. In some embodiments, the flexible substrate has a first side and an opposing second side. In some embodiments, the substrate film is of a clear or colorless polyimide.

At step 1104, one or more openings, holes or vias are formed in the substrate film by an ultraviolet (UV) based laser, a carbon dioxide based laser, or by any other known methods, such as, but not limited to, mechanical drilling, depth-controlled laser drilling or punching. In some embodiments, the one or more vias extend through the substrate layer and the first and second opposing sides. In various embodiments, one or more through-hole, blind and/or buried vias may be formed depending upon the desired design and surface mount of the FCB. At step 1106, the one or more openings, holes or vias are cleaned or de-smeared using plasma cleaning to remove unwanted residue or by-products left behind by laser or mechanical drilling.

At step 1108a, in some embodiments, first and second conducting layers are formed on the first and second sides, respectively, of the substrate as well as through the at least one via. In some embodiments, each of the first and second conducting layers comprises first and second metallic tie-coat layers such as, for example, of nickel, chromium or a metallic alloy followed by first and second layers of copper. In alternate embodiments, each of the first and second conducting layers comprise only copper.

At step 1110a, a light sensitive dry film photoresist is applied on the first and second conducting layers followed by exposing the photoresist to light and developing in the area of the at least one via as well as in traces that would later be metallized to form first and second circuit patterns on the first and second sides of the substrate. At step 1112a, the substrate is immersed in a series of copper plating baths to electrolytically deposit copper to the traces developed at step 1110a (thereby forming first and second circuit patterns on the first and second sides of the substrate) and to fill the at least one via with copper. At step 1114a, fabrication steps comprise plating tin over the copper to protect the traces during etching, stripping the resist, and etching copper and then the tin.

In alternate embodiments, at step 1108b, surfaces on the first and second sides of the substrate are panel plated, using copper, and the at least one via is also simultaneously filled with copper. At step 1110b, a light sensitive dry film photoresist is applied on the first and second copper plated sides of the substrate followed by exposing the photoresist to light, and etching the copper between traces (to form first and second circuit patterns) and eventually stripping the resist.

At step 1116, the first and second sides of the substrate are encapsulated with first and second cover layers, respectively, using methods such as, for example, inkjet printing, screen printing or vacuum lamination of dry film. In some embodiments, the first and second cover layers may have certain surfaces, surface portions or surface areas exposed to enable an end-user to attach necessary components at the exposed surfaces. For example, the end-user may attach surface mountable components such as, for example, resistors, capacitors, BGA package, or any pin connector through a plated through hole. At step 1118, in some embodiments, the exposed surfaces are subjected to a surface finish process to prevent the underlying conductive traces (of copper, for example) from oxidizing or corroding. The surface finish processes comprise treatments such as, but not limited to, ENIG (Electroless Nickel Immersion Gold), silver, tin, ENEPIG (Electroless Nickel Electroless Palladium Immersion Gold) and solder. Finally, at step 1120, electrical testing of the FCB is conducted. In some embodiments, the electrical testing is a continuity check for shorts, opens and voltage leakage. In embodiments, where fabrication of a plurality of FCBs is done on a single panel, each of the plurality of FCBs is laser routed (or alternatively, mechanically routed) for singulation. The FCBs are subjected to final inspection and testing.

### A Third Embodiment Of The Manufacturing Process

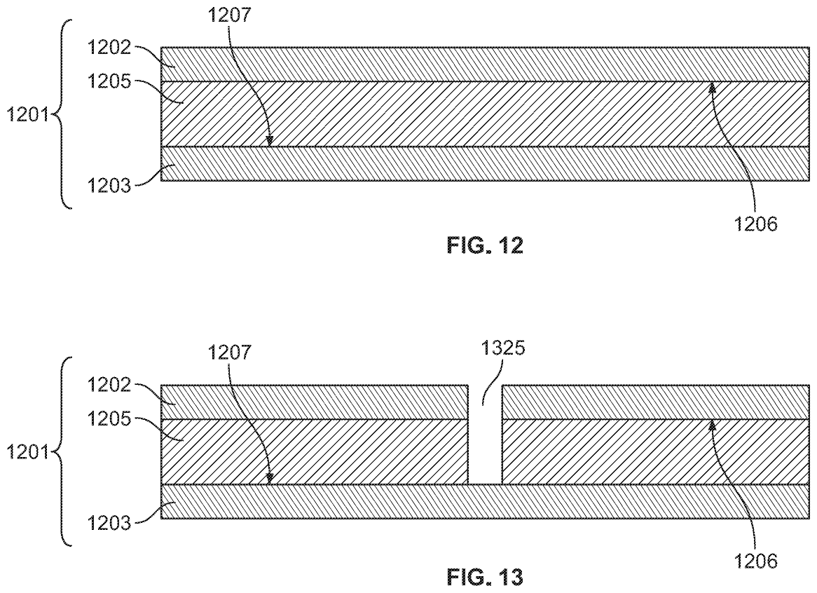

FIG. 12 illustrates a cross-sectional view of a flexible conductor-clad base film 1201, in accordance with embodiments of the present specification. Referring to FIG. 12, the starting material of an FCB is the flexible conductor-clad base film 1201 comprising a substrate layer 1205 having a first side 1206 and an opposing second side 1207. The substrate layer 1205 has a first conducting layer 1202 laminated to the first side 1206 and a second conducting layer 1203 laminated to the second side 1207 of the substrate layer 1205 thereby resulting in the flexible base film 1201.

In some embodiments, the first and second conducting layers 1202, 1203 comprise metal foils such as, for example, copper foil, aluminum foil, copper-beryllium alloy, or a metal filled conductive polymer.

In some embodiments, the flexible base film 1201 is a substantially rectangular strip of a predetermined length to support fabrication, thereon, of at least one FCB. In some embodiments, the flexible base film 1201 is received in the form of a roll or sheet and cut to size in order to fabricate at least one FCB thereon. In some embodiments, the flexible base film 1201 has the first conducting layer 1202 of thickness ranging from 5 micron to 18 micron, the substrate layer 1205 of thickness ranging from 12 micron to 25 micron and the second conducting layer 1203 of thickness ranging from 5 micron to 18 micron. In various embodiments, a thickness of the substrate layer 1205 may range from 12 micron to 75 micron.

FIG. 13 illustrates a cross-sectional view of the base film 1201 with at least one formed opening, hole or via, in accordance with some embodiments. Referring now to FIG. 13, at least one opening, hole or via 1325 is formed in the base film 1201 by an ultraviolet (UV) based laser, a carbon dioxide based laser, or by any other known methods, such as, but not limited to, mechanical drilling, depth-controlled laser drilling or punching. In an embodiment, for exemplary illustrative purposes, the at least one via 1325 is shown as a single blind via. However, in alternate embodiments a plurality of through-hole, blind and/or buried vias may be formed depending upon the desired design and surface mount of the FCB. It should be appreciated that through-hole vias are easier to drill and have no contamination issues that are typical at the bottom of blind vias.

Once the at least one opening, hole or via 1325 is formed in the base film 1201 the via is cleaned or de-smeared using plasma cleaning to remove unwanted residue or by-products left behind by laser or mechanical drilling of the at least one via 1325.

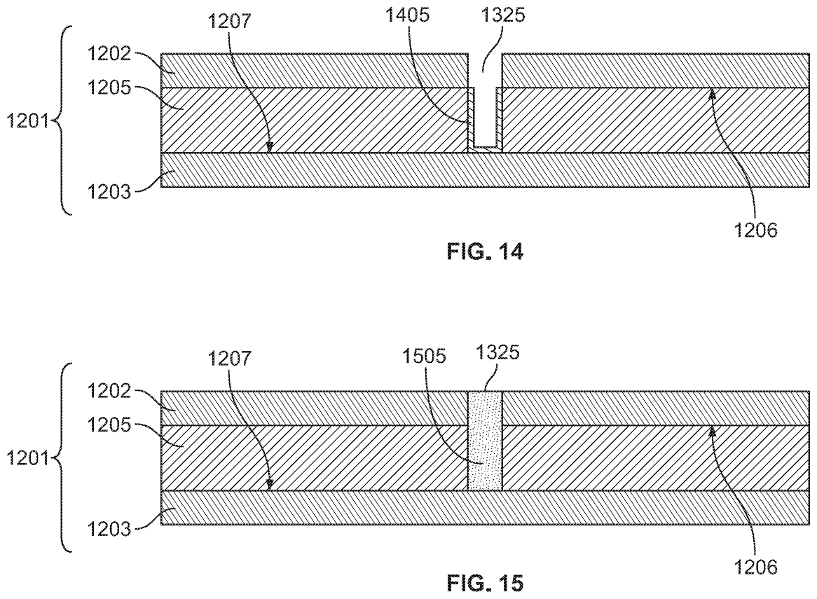

In some embodiments, as shown in FIG. 14, the at least one via 1325 is subjected to shadow plating wherein the base film 1201 is immersed in a solution with conductive carbon or graphite particles. The carbon or graphite adheres to the entire surface, creating a thin layer 1405. A micro-etch is then performed that removes the carbon or graphite from the conducting layer 1202, within the at least one via 1325, so that only the dielectric areas (within at least one via 1325) remain coated with the thin layer or conductive bridge 1405 of carbon or graphite.

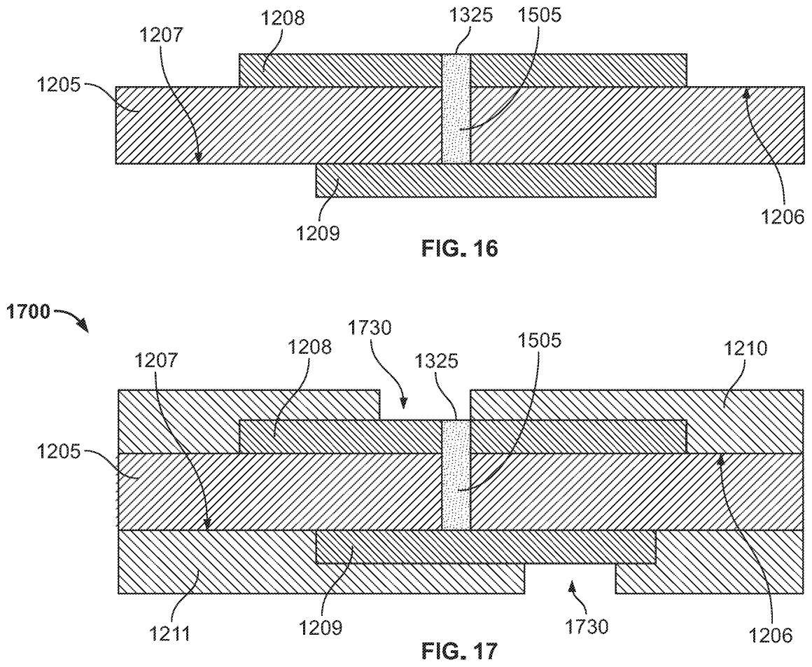

In one embodiment, as shown in FIG. 15, the base film 1201 of FIG. 14 is subjected to panel plating to fill the at least one via 1325 with conductive material 1505 such as, but not limited to, copper. Subsequently, as shown in FIG. 16, first and second circuit patterns 1208, 1209 are formed, on first and second sides 1206, 1207, by depositing conductive ink using the inkjet printing process. Unwanted conducting material, of the first and second conducting layers 1202, 1203, is then etched leaving conductive ink traces of the first and second circuit patterns 1208, 1209.

In another embodiment, instead of panel plating, the base film 1201 of FIG. 14 is subjected to pattern plating wherein conducting material such as, for example, copper is deposited on selected areas (on the first and second sides 1206, 1207) as an imaged photoresist coating is used to define patterns or layouts (corresponding to first and second circuit patterns 1208, 1209). In this embodiment, after imaging the photoresist, the next step is to plate copper and then follow up with a tin plating that acts as an etch resist. Thereafter, the photoresist is stripped away leaving first and second circuit patterns 1208, 1209 of tin plating on copper. The tin acts as an etch resist as the unwanted copper is etched away. The tin is then stripped off leaving just the plated up copper traces of the first and second circuit patterns 1208, 1209.

Referring back to FIG. 14, in alternate embodiments, once the at least one via 1325 is formed and plasma cleaned, it is filled with a conductive paste. The conductive paste forms an electrical/conductive medium connecting the first and second circuit patterns 1208, 1209 that are formed by application of resist, followed by deposition of conductive ink using the inkjet printing process and thereafter etching unwanted conducting material, of the first and second conducting layers 1202, 1203, leaving conductive ink traces of the first and second circuit patterns 1208, 1209 as described with reference to FIG. 16.

As a next step, as shown in FIG. 17, in some embodiments, first and second cover layers 1210, 1211 are deposited or formed using methods such as, for example, the inkjet printing process described earlier with reference to FIG. 4B, screen printing or vacuum lamination of dry film. Consequently, the first and second sides 1206, 1207 are respectively encapsulated by the first and second cover layers or films 1210, 1211 to protect the formed first and second circuit patterns 1208, 1209, comprising conductive trace patterns and pads, against oxidation and mechanical stress or wear. In some embodiments, the first and second cover layers 1210, 1211 comprise clear or colorless material such as, but not limited to, clear/colorless polyimide.

As shown in FIG. 17, the FCB 1700 encapsulated with the first and second cover layers 1210, 1211 may have certain conducting surfaces, surface portions or surface areas 1730 exposed to enable an end-user to attach necessary components at the exposed surfaces. For example, the end-user may attach surface mountable components such as, for example, resistors, capacitors, BGA package, or any pin connector through a plated through hole. In some embodiments, the exposed surfaces 1730 are subjected to a surface finish process to prevent the underlying conductive traces (of copper, for example) from oxidizing or corroding. The surface finish processes comprise treatments such as, but not limited to, ENIG (Electroless Nickel Immersion Gold), silver, tin, ENEPIG (Electroless Nickel Electroless Palladium Immersion Gold) and solder.

Thereafter, electrical testing of the FCB 1700 is conducted. In some embodiments, the electrical testing is a continuity check for shorts, opens and voltage leakage. In embodiments, where fabrication of a plurality of FCBs is done on a single panel, each of the plurality of FCBs is laser routed (or alternatively, mechanically routed) for singulation. The FCBs are subjected to final inspection and testing.

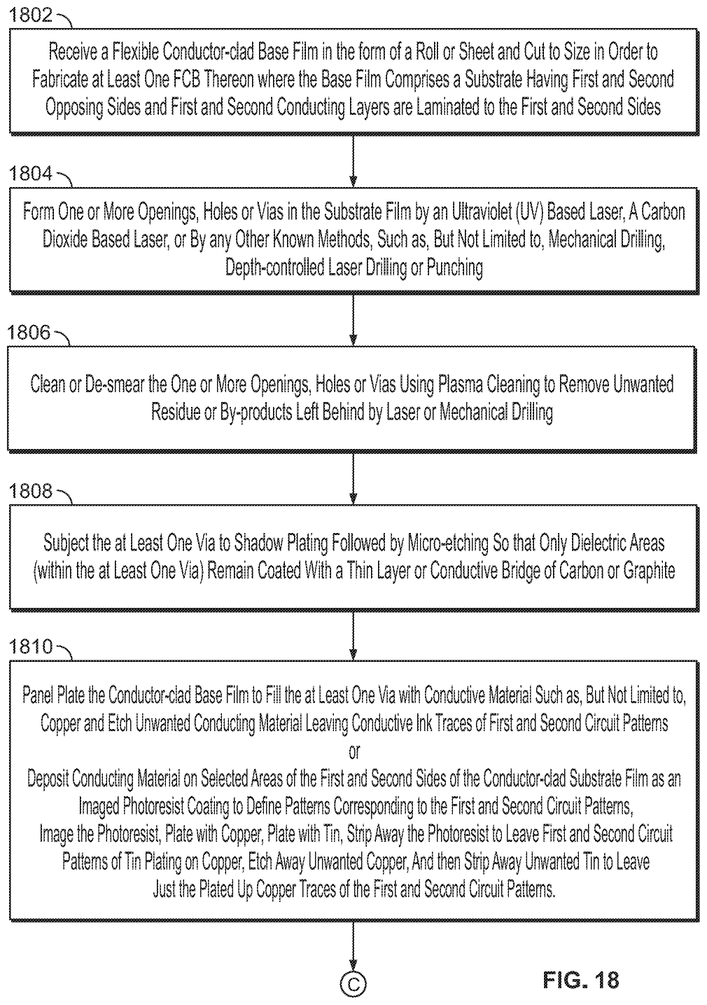

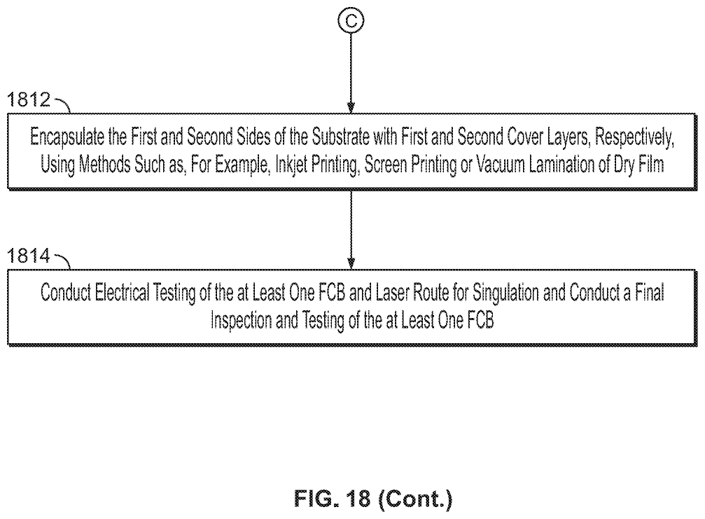

FIG. 18 is a flowchart of a plurality of exemplary steps of a third method of manufacturing an FCB, in accordance with some embodiments of the present specification. At step 1802, a flexible conductor-clad base film is received in the form of a roll or sheet and cut to size in order to fabricate at least one FCB thereon. In some embodiments, the flexible conductor-clad base film comprises a substrate layer having a first side and an opposing second side. The substrate layer has a first conducting layer laminated to the first side and a second conducting layer laminated to the second side of the substrate layer thereby resulting in the flexible base film. In some embodiments, the substrate layer is of a clear or colorless polyimide.

At step 1804, at least one opening, hole or via is formed in the substrate film by an ultraviolet (UV) based laser, a carbon dioxide based laser, or by any other known methods, such as, but not limited to, mechanical drilling, depth-controlled laser drilling or punching. In some embodiments, the at least one via comprises a single blind via. In various embodiments, however, one or more through-hole, blind and/or buried vias may be formed depending upon the desired design and surface mount of the FCB. At step 1806, the one or more openings, holes or vias are cleaned or de-smeared using plasma cleaning to remove unwanted residue or by-products left behind by laser or mechanical drilling.

At step 1808, the at least one via is subjected to shadow plating followed by micro-etching so that only the dielectric areas (within the at least one via) remain coated with a thin layer or conductive bridge of carbon or graphite.

In one embodiment, at step 1810, the conductor-clad base film is subjected to panel plating to fill the at least one via with conductive material such as, but not limited to, copper. Unwanted conducting material is then etched leaving conductive ink traces of first and second circuit patterns. In an alternate embodiment, the conductor-clad base film is subjected to pattern plating wherein conducting material such as, for example, copper is deposited on selected areas (on the first and second sides of the substrate film) as an imaged photoresist coating is used to define patterns or layouts corresponding to first and second circuit patterns. In this embodiment, after imaging the photoresist, the next step is to plate copper and then follow up with tin plating. Thereafter, the photoresist is stripped away leaving first and second circuit patterns of tin plating on copper. The tin acts as an etch resist as the unwanted copper is etched away. The tin is then stripped off leaving just the plated up copper traces of the first and second circuit patterns.

At step 1812, the first and second sides of the substrate are encapsulated with first and second cover layers, respectively, using methods such as, for example, inkjet printing, screen printing or vacuum lamination of dry film.

Finally, at step 1814, electrical testing of the FCB is conducted. In some embodiments, the electrical testing is a continuity check for shorts, opens and voltage leakage. In embodiments, where fabrication of a plurality of FCBs is done on a single panel, each of the plurality of FCBs is laser routed (or alternatively, mechanically routed) for singulation. The FCBs are subjected to final inspection and testing.

The above examples are merely illustrative of the many applications of the system and method of present specification. Although only a few embodiments of the present specification have been described herein, it should be understood that the present specification might be embodied in many other specific forms without departing from the spirit or scope of the specification. Therefore, the present examples and embodiments are to be considered as illustrative and not restrictive, and the specification may be modified within the scope of the appended claims.

We claim:

1. A flexible circuit board comprising:
a substrate having a first side and an opposing second side, wherein the substrate comprises a colorless polyimide;
a first circuit pattern formed by a deposition of ink on the first side;
a second circuit pattern formed by a deposition of ink on the second side;
at least one opening to interconnect the first circuit pattern to the second circuit pattern;
a first cover layer applied on the first circuit pattern, wherein the first cover layer comprises a colorless polyimide; and
a second cover layer applied on the second circuit pattern, wherein the second cover layer comprises a colorless polyimide.

2. The flexible circuit board of claim 1, wherein a thickness of the substrate ranges from 12 μm to 75 μm.

3. The flexible circuit board of claim 1, wherein a thickness of the first cover layer and the second cover layer each range from 12 μm to 25 μm.

4. The flexible circuit board of claim 1, wherein the at least one opening has a diameter ranging from 18 μm to 50 μm.

5. The flexible circuit board of claim 1, wherein the first circuit pattern is formed by conveying the first side passed a first print head of a printer and wherein the second circuit pattern is formed by conveying the second side passed the first print head of the printer.

6. The flexible circuit board of claim 1, wherein the ink comprises an infusion of nanoparticles of a conductive material comprising at least one of copper, silver or gold.

7. The flexible circuit board of claim 1, wherein the first cover layer is formed by conveying the first side passed a second print head of a printer and wherein the second cover layer is formed by conveying the second side passed the second print head of the printer.

8. The flexible circuit board of claim 1, wherein the at least one opening comprises ink and wherein the ink is deposited into the at least one opening during the deposition of the ink on at least one of the first side and the second side.

9. A method of manufacturing a flexible circuit board, the method comprising:
obtaining a substrate having a first side and an opposing second side, wherein the substrate comprises a colorless polyimide;
forming at least one opening, wherein said at least one opening extends through the substrate and interconnects the first side to the second side;
depositing a first circuit pattern of ink on the first side of the substrate using a first print head of a printer;
depositing a second circuit pattern of ink on the second side of the substrate using the first print head of the printer;
depositing a first cover layer on the first side of the substrate using a second print head of the printer; and
depositing a second cover layer on the second side of the substrate using the second print head of the printer, wherein the first and second cover layers do not cover at least portion of a surface of the first circuit pattern or the second circuit pattern.

10. The method of manufacturing of claim 9, wherein a thickness of the substrate ranges from 12 μm to 75 μm.

11. The method of manufacturing of claim 9, wherein a thickness of the first cover layer or the second cover layer ranges from 12 μm to 25 μm.

12. The method of manufacturing of claim 9, wherein the at least one opening has a diameter ranging from 18 μm to 50 μm.

13. The method of manufacturing of claim 9, wherein the first side of the substrate is conveyed passed the first print head of the printer configured to deposit the first circuit pattern and wherein the second side of the substrate is conveyed passed the first print head of the printer configured to deposit the second circuit pattern.

14. The method of manufacturing of claim 9, wherein the ink comprises an infusion of nanoparticles of a conductive material comprising at least one of copper, silver or gold.

15. The method of manufacturing of claim 9, wherein the first side of the substrate is conveyed facing the second print head of the printer configured to deposit the first cover layer and wherein the second side of the substrate is conveyed facing the second print head of the printer configured to deposit the second cover layer.

16. The method of manufacturing of claim 9, further comprising filling the at least one opening with ink concurrent to depositing the ink on at least one of the first side or second side.

17. A method of manufacturing a flexible circuit board, the method comprising:
obtaining a substrate having first and second opposing sides, wherein the substrate comprises a colorless polyimide;
forming at least one opening, wherein the at least one opening extends through the substrate and interconnects the first side with the opposing second side;
panel plating the first side and the second side of the substrate using a conducting metal;
applying a photoresist on the first side and the second side;
exposing the photoresist to light;
etching the conducting metal to form a first circuit pattern on the first side and a second circuit pattern on the second side; and
encapsulating the first side with a first cover layer and the second side with a second cover layer, and wherein the first and second cover layers are positioned to not cover at least a portion of a surface of the first circuit pattern or a surface of the second circuit pattern, thereby leaving said surface of the first circuit pattern or said surface of the second circuit pattern exposed; and
subjecting said exposed surface of the first circuit pattern or said exposed surface of the second circuit pattern to a surface finish process.

18. The method of claim 17, wherein each of the first cover layer and the second cover layer is applied using at least one of inkjet printing, screen printing or vacuum lamination of dry film.

19. The method of claim 17, further comprising filling the at least one opening with the conducting metal concurrent with the panel plating of at least one of the first side or the second side.

20. The method of claim 17, wherein a thickness of the substrate ranges from 12 μm to 75 μm.
